(19) United States
(12) Patent Application Publication
(10) Pub. No.: US 2011/0001418 A1
(43) Pub. Date: Jan. 6, 2011

(54) HIGH HEAT DISSIPATION ELECTRIC CIRCUIT BOARD AND MANUFACTURING METHOD THEREOF

(76) Inventor: Chi-Ruei TSAI, Taipei City (TW)

Correspondence Address: Guice Patents PLLC, 12647 Galveston Court #302, Manassas, VA, 20112, US

(21) Appl. No.: 12/830,527

(22) Filed: Jul. 6, 2010

(30) Foreign Application Priority Data
Jul. 3, 2009 (TW) 098122511

(51) Int. Cl. H01J 61/52; H05K 3/10; H05K 1/00

(52) U.S. Cl. 313/46; 29/846; 174/252

(57) ABSTRACT

The present invention relates to a high heat dissipation electric circuit board, comprises: an electric conductive wiring layer serving to be installed with at least one electronic unit, on which a wiring is formed for being connected to the electronic unit; an insulation layer, installed on one side of the electric conductive wiring layer; and a graphite heat conduction layer, installed on one side of the insulation layer for uniformly dissipating heat generated by the electronic unit. Moreover, the present invention also provides a manufacturing method of high heat dissipation electric circuit board.

### BACKGROUND OF THE INVENTION

1. Field of the Invention

The present invention relates to an electric circuit board and manufacturing method thereof, especially to a high heat dissipation electric circuit board and manufacturing method thereof wherein graphite material is utilized to form a heat conduction layer for lowering the production cost and increasing the heat dissipation efficiency.

2. Description of Related Art

The petrol price has been going up so a trend of energy saving and reducing carbon consumption is raised for slowing down the consumption of natural recourses, and also slowing the global warming.

For energy saving and reducing carbon consumption, manufacturers in various countries have launched products corresponding to said issues, for example vehicle manufacturers produce oil/electricity hybrid vehicle or electric vehicle; electronic goods manufacturers produce various environmental friendly electronic devices or lamps; wherein there is one product holding the most expectation for saving energy, which is a light emitting diode (LED) lamp, for example a LED street lamp or LED bulb. According to research, electricity consumption is greatly reduced by using LED street lamps or LED bulbs, i.e. achieving the purpose of saving energy and reducing carbon consumption.

A general LED street lamp or LED bulb utilize high-brightness light emitting diodes, the cost is relatively higher comparing to conventional lamps; and when in use, the high-brightness light emitting diodes would generate large amount of heat, so if heat dissipation is poor, the high-brightness light emitting diodes may be burned or damaged.

Therefore a heat conduction layer is installed on an electric circuit board of general LED lamp, heat generated by light emitting diodes can be rapidly dissipated through the heat conduction layer for preventing the high-brightness light emitting diodes from being burned or damaged. However, a conventional heat conduction layer is made of metal material such as copper or aluminum; compared to a heat conduction layer made of graphite, it has following disadvantages: 1. production cost is higher than being made of graphite; and 2. the thermal conductivity coefficient thereof is smaller than that of the graphite.

For improving the mentioned disadvantages, the present invention provides a high heat dissipation electric circuit board and manufacturing method thereof.

### SUMMARY OF THE INVENTION

One primary object of the present invention is to provide a high heat dissipation electric circuit board and manufacturing method thereof in which graphite material is utilized to form a heat conduction layer for lowering the production cost.

Another object of the present invention is to provide a high heat dissipation electric circuit board and manufacturing method thereof in which graphite material is utilized to form a heat conduction layer for uniformly dissipating heat so as to increase the heat dissipation efficiency.

For achieving the mentioned objects, the present invention provides a high heat dissipation electric circuit board, comprises: an electric conductive wiring layer serving to be installed with at least one electronic unit, on which a wiring is formed for being connected to the electronic unit; an insulation layer, installed on one side of the electric conductive wiring layer; and a graphite heat conduction layer, installed on one side of the insulation layer for uniformly dissipating heat generated by the electronic unit.

For achieving the mentioned objects, the present invention provides a manufacturing method of high heat dissipation electric circuit board, comprises the steps of: manufacturing an electric conductive wiring layer with a metal substance or an alloy thereof; forming at least one wiring on the electric conductive wiring layer; manufacturing an insulation layer with an insulation substance; and installing a graphite heat conduction layer on one side of the insulation layer.

### BRIEF DESCRIPTION OF THE DRAWINGS

FIG. 1 is a cross sectional view of the high heat dissipation electric circuit board of one preferred embodiment of the present invention;

FIG. 2 is a cross sectional view illustrating the high heat dissipation electric circuit board of the present invention being further installed with a plurality of fins;

FIG. 3 is a flow chart illustrating the manufacturing method of high heat dissipation electric circuit board of another preferred embodiment of the present invention.

### DETAILED DESCRIPTION OF THE PREFERRED EMBODIMENT

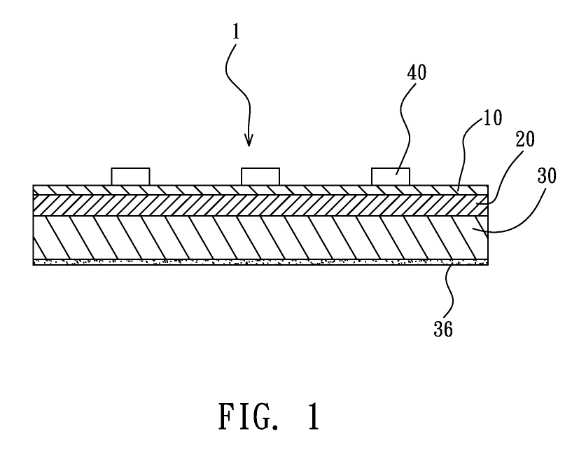

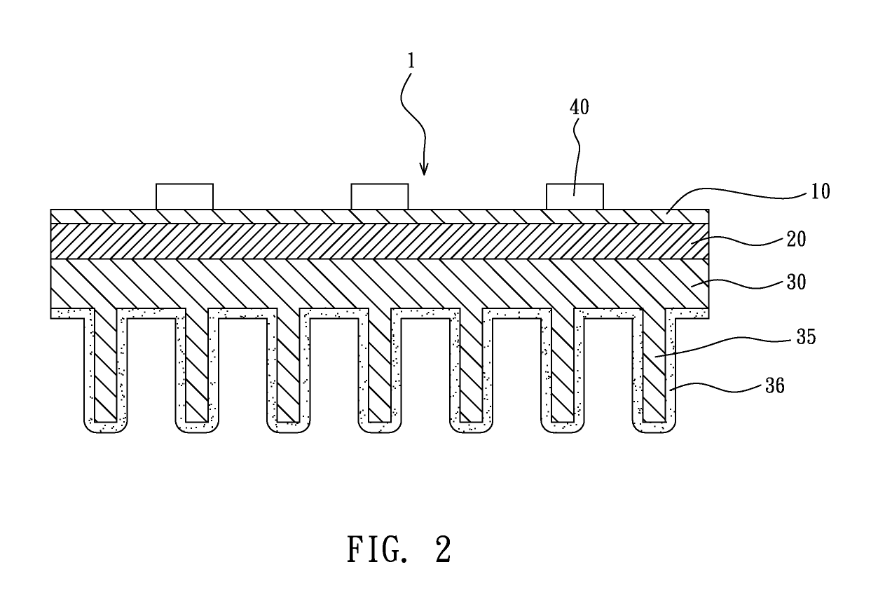

Referring to FIG. 1 and FIG. 2, wherein FIG. 1 is a cross sectional view of the high heat dissipation electric circuit board of one preferred embodiment of the present invention; and FIG. 2 is a cross sectional view illustrating the high heat dissipation electric circuit board of the present invention being further installed with a plurality of fins.

As shown in figures, the high heat dissipation electric circuit board 1 provided by the present invention comprises: an electric conductive wiring layer 10; an insulation layer 20; and a graphite heat conduction layer 30.

The electric conductive wiring layer 10 is served to be installed with at least one electronic unit 40, e.g. but not limited to a high-brightness LED chip, a wiring (not shown) is arranged on the electric conductive wiring layer 10 for being connected to the electronic unit 40. The electric conductive wiring layer 10 is made of, e.g. but not limited to, gold, silver, copper or an alloy thereof through means of printing, laminating, thermal pressing, vapor depositing or electroplating. And the wiring thereof is formed with an etching means, which is a conventional art and is not the feature of the present invention, therefore no further illustration is provided.

The insulation layer 20 is installed on one end of the electric conductive wiring layer 10, e.g. but not limited to the bottom end. The insulation layer 20 is made of, e.g. but not limited to, polymer material which can be epoxy or epoxy containing glass fibers. The insulation layer 20 can also be made of ceramic powders, the ceramic powders are, e.g. but not limited to, Aluminum oxide (Al₂O₃), aluminum nitride (AlN), silicon carbide (SiC) or boron nitride (BN).

The graphite heat conduction layer 30 is made of graphite material, and is installed on one end of the insulation layer 20, e.g. but not limited to the bottom end, such that heat generated by the electronic unit 40 is able to be uniformly dispersed. As mentioned, the thermal conductivity coefficient (K) of copper is 360 W/MK, the thermal conductivity coefficient (K) of the aluminum is 270 W/MK; and the graphite is a crystalline material, the thermal conductivity coefficient (K) of X and Y axle directions thereof is 400 W/MK, and the thermal conductivity coefficient (K) of Z axle direction thereof is 70˜80 W/MK, and the smaller of the grains, the higher of the thermal conductivity coefficient, the thermal conductivity coefficient can be even higher than 1000 W/MK, and the material cost thereof is half or one third of that of the copper or aluminum. So the graphite heat conduction layer 30 provided by the present invention can effectively conduct the heat generated by the electronic unit 40 from a point state to a surface state, so subsequent heat dissipation device is able to be more efficiently utilized. Moreover, the color of graphite is black so the graphite material itself has thermal radiation capacity. The high heat dissipation electric circuit board 1 of the present invention utilizes the graphite heat conduction layer 30 to lower the production cost and also to rapidly dissipate the heat generated by the electronic unit 40, so the electronic unit 40 is prevented from being burned or damaged by high temperature. Thus the high heat dissipation electric circuit board 1 provided by the present invention is novel comparing to conventional high heat dissipation electric circuit boards.

As shown in FIG. 2, a surface of the graphite heat conduction layer 30 of the high heat dissipation electric circuit board 1 of the present invention is further provided with a plurality of fins 35 for increasing the heat dissipation area and the heat dissipation efficiency. Moreover, because the graphite heat conduction layer 30 is fragile and easy to be broken into pieces, a metal layer 36 is covered on the surface of the graphite heat conduction layer 30 of the present invention for avoiding breakings of the graphite heat conduction layer 30. When in use, the heat generated by the electronic unit 40 is able to be uniformly dispersed to the surface of the graphite heat conduction layer 30, so the purpose of rapid heat dissipation is achieved through thermal radiation of the plural fins 35 and heat exchange with air in a larger area means.

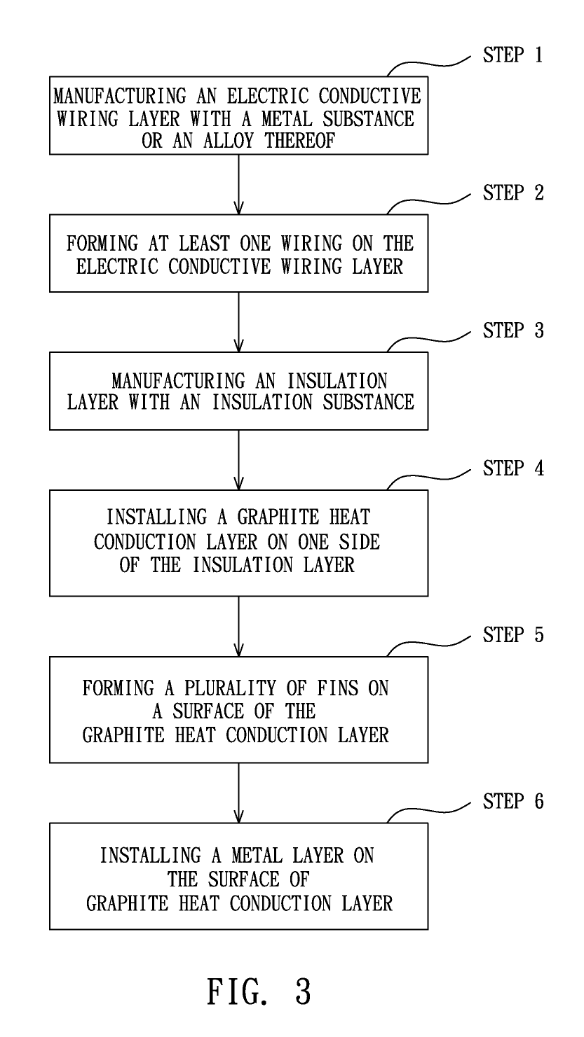

Referring to FIG. 3, which is a flow chart illustrating the manufacturing method of high heat dissipation electric circuit board of another preferred embodiment of the present invention.

As shown in FIG. 3, the manufacturing method of high heat dissipation electric circuit board provided by the present invention comprises the steps of: STEP 1: manufacturing an electric conductive wiring layer 10 with a metal substance or an alloy thereof; STEP 2: forming at least one wiring on the electric conductive wiring layer 10; STEP 3: manufacturing an insulation layer 20 with an insulation substance; and STEP 4: installing a graphite heat conduction layer 30 on one side of the insulation layer 20.

In the STEP 1: manufacturing an electric conductive wiring layer 10 with a metal substance or an alloy thereof; wherein the electric conductive wiring layer 10 is made of, e.g. but not limited to, gold, silver, copper or an alloy thereof through means of printing, laminating, thermal pressing, vapor depositing or electroplating. And the wiring thereof is formed with a means of, e.g. but not limited to, etching, which is a conventional art and is not the feature of the present invention, therefore no further illustration is provided.

In the STEP 2: forming at least one wiring on the electric conductive wiring layer 10; wherein the wiring (not shown) is formed with a means of, e.g. but not limited to, etching.

In the STEP 3: manufacturing an insulation layer 20 with an insulation substance; wherein the insulation substance is a polymer material or ceramic powders, the connecting method for the insulation layer 20 and the graphite heat conduction layer 30 is altered with respect to different materials. For instance, when the insulation substance is a polymer material, e.g. but not limited to epoxy or epoxy containing glass fibers, the connecting method for the insulation layer 20 and the graphite heat conduction layer 30 can be lamination or thermal pressing.

When the insulation substance is ceramic powders, e.g. but not limited to Aluminum oxide (Al₂O₃), aluminum nitride (AlN), silicon carbide (SiC) or boron nitride (BN), an acid solution capable of solving the ceramic powders is served as a carrier, and a part or all of the ceramic powders is solved in the carrier, and uniformly coated or applied on the graphite heat conduction layer 30 for being combined with the graphite heat conduction layer 30. The acid solution is, e.g. but not limited to, nitric acid, hydrochloric acid or phosphoric acid.

Or when the insulation substance is ceramic powders, an acid solution capable of solving the ceramic powders is served as a carrier, and the carrier is vaporized through high temperature so as to combine the insulation layer 20 and the graphite heat conduction layer 30.

Or when the insulation substance is ceramic powders, an acid solution capable of solving the ceramic powders is served as a carrier, and the carrier is vaporized through a high-temperature thermal pressing means so as to combine the insulation layer 20 and the graphite heat conduction layer 30.

Or when the insulation substance is ceramic powders, an alkaline solution is provided for neutralizing the acid carrier, and the ceramic powder solved in the acid carrier are released to form a film layer (not shown), then the carrier is vaporized by high temperature so as to combine the insulation layer 20 and the graphite heat conduction layer 30; wherein the alkaline solution is e.g. but not limited to sodium hydroxide.

Or when the insulation substance is ceramic powders, an alkaline solution is provided for neutralizing the acid carrier, and the ceramic powder solved in the acid carrier are released to form a film layer, then the carrier is vaporized through a high-temperature thermal pressing means so as to combine the insulation layer 20 and the graphite heat conduction layer 30; wherein the alkaline solution is e.g. but not limited to sodium hydroxide.

Or when the insulation substance is ceramic powders, a solution incapable of solving the ceramic powders is served as a carrier, and is uniformly coated or supplied on the graphite heat conduction layer 30, then the carrier is vaporized through a first-stage high temperature, then the temperature is heated to a second-stage high temperature capable of softening the ceramic powders, in said temperature the ceramic powders would sinter and combine with each other so as to combine the insulation layer 20 and the graphite heat conduction layer 30; wherein the solution is e.g. but not limited to pure water.

Or when the insulation substance is ceramic powders, the carrier can be vaporized through a first-stage high temperature obtained by a means of high temperature thermal pressing, then the temperature is heated to a second-stage high temperature capable of softening the ceramic powders, in said temperature the ceramic powders would sinter and combine with each other so as to combine the insulation layer 20 and the graphite heat conduction layer 30.

In the STEP 4: installing a graphite heat conduction layer 30 on one side of the insulation layer 20; the connecting method is as what is disclosed in the STEP 3. Moreover, in the STEP 4, for preventing the graphite heat conduction layer 30 from oxidizing under high temperature, inert gas is provided and served as a protection gas during the high temperature processing of the graphite heat conduction layer 30 for avoiding oxidization; wherein the inset gas is nitrogen.

Moreover, the manufacturing method of high heat dissipation electric circuit board of the present invention further includes a STEP 5: forming a plurality of fins 35 on a surface of the graphite heat conduction layer 30; the plural fins 35 can increase the heat exchange area with air for increasing the heat dissipation efficiency.

Moreover, the manufacturing method of high heat dissipation electric circuit board of the present invention further includes a STEP 6: installing a metal layer 36 on the surface of graphite heat conduction layer 30, for preventing the graphite heat conduction layer 30 from powdering. Thus the manufacturing method of high heat dissipation electric circuit board provided by the present invention is novel comparing to conventional manufacturing method of high heat dissipation electric circuit board.

As mentioned above, with the high heat dissipation electric circuit board provided by the present invention, graphite material is utilized to form the heat conduction layer for lowering the production cost and also for uniformly dissipating heat so as to increase the heat dissipation efficiency. Thus the high heat dissipation electric circuit board provided by the present invention is novel comparing to conventional high heat dissipation electric circuit boards.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A high heat dissipation electric circuit board, comprising:
an electric conductive wiring layer serving to be installed with at least one electronic unit, on which a wiring being formed for being connected to said electronic unit;
an insulation layer, installed on one side of said electric conductive wiring layer; and
a graphite heat conduction layer, installed on one side of said insulation layer for uniformly dissipating heat generated by said electronic unit.

2. The high heat dissipation electric circuit board as claimed in claim 1, wherein said electric conductive wiring layer is made of gold, silver, copper or an alloy thereof through means of printing, laminating, thermal pressing, vapor depositing or electroplating.

3. The high heat dissipation electric circuit board as claimed in claim 1, wherein said insulation layer is made of polymer material, said polymer material is epoxy or epoxy containing glass fibers.

4. The high heat dissipation electric circuit board as claimed in claim 1, wherein said insulation layer is made of ceramic powders, said ceramic powders is aluminum oxide (Al₂O₃), aluminum nitride (AlN), silicon carbide (SiC) or boron nitride (BN).

5. The high heat dissipation electric circuit board as claimed in claim 1, wherein said electronic unit is a light emitting diode chip.

6. The high heat dissipation electric circuit board as claimed in claim 1, wherein said graphite heat conduction layer is further installed with a plurality of fins.

7. The high heat dissipation electric circuit board as claimed in claim 1, wherein a surface of said graphite heat conduction layer is further covered by a metal layer, for preventing said graphite heat conduction layer from powdering.

8. A manufacturing method of high heat dissipation electric circuit board, comprising the steps of:
manufacturing an electric conductive wiring layer with a metal substance or an alloy thereof;
forming at least one wiring on said electric conductive wiring layer;
manufacturing an insulation layer with an insulation substance; and
installing a graphite heat conduction layer on one side of said insulation layer.

9. The manufacturing method of high heat dissipation electric circuit board as claimed in claim 8, wherein said electric conductive wiring layer is made of gold, silver, copper or an alloy thereof through means of printing, laminating, thermal pressing, vapor depositing or electroplating.

10. The manufacturing method of high heat dissipation electric circuit board as claimed in claim 8, wherein said insulation layer is made of polymer material and is combined with said graphite heat conduction layer through means of laminating or thermal pressing; said polymer material is epoxy or epoxy containing glass fibers.

11. The manufacturing method of high heat dissipation electric circuit board as claimed in claim 8, wherein said insulation layer is made of ceramic powders, an acid solution capable of solving said ceramic powders is served as a carrier, and a part or all of said ceramic powders is solved in said carrier, and uniformly coated or applied on said graphite heat conduction layer for being combined with said graphite heat conduction layer; wherein said ceramic powders is aluminum oxide (Al₂O₃), aluminum nitride (AlN), silicon carbide (SiC) or boron nitride (BN).

12. The manufacturing method of high heat dissipation electric circuit board as claimed in claim 11, wherein said insulation layer is made of ceramic powders, an acid solution capable of solving said ceramic powders is served as a carrier, and said carrier is vaporized through high temperature so as to combine said insulation layer and said graphite heat conduction layer.

13. The manufacturing method of high heat dissipation electric circuit board as claimed in claim 11, wherein said insulation layer is made of ceramic powders, an acid solution capable of solving said ceramic powders is served as a carrier, and said carrier is vaporized through a high-temperature thermal pressing means so as to combine said insulation layer and said graphite heat conduction layer.

14. The manufacturing method of high heat dissipation electric circuit board as claimed in claim 11, wherein said insulation layer is made of ceramic powders, an alkaline solution is provided for neutralizing said acid carrier, and said ceramic powders solved in said acid carrier are released to form a film layer, then said carrier is vaporized by high temperature so as to combine said insulation layer and said graphite heat conduction layer; wherein said alkaline solution is sodium hydroxide.

15. The manufacturing method of high heat dissipation electric circuit board as claimed in claim 11, wherein said insulation layer is made of ceramic powders, an alkaline solution is provided for neutralizing said acid carrier, and said ceramic powders solved in said acid carrier are released to form a film layer, then said carrier is vaporized through a high-temperature thermal pressing means so as to combine said insulation layer and said graphite heat conduction layer; wherein said alkaline solution is sodium hydroxide.

16. The manufacturing method of high heat dissipation electric circuit board as claimed in claim 11, wherein said insulation layer is made of ceramic powders, a solution incapable of solving said ceramic powders is served as a carrier, and is uniformly coated or supplied on said graphite heat conduction layer, said carrier is vaporized through a first-stage high temperature, then said temperature is heated to a second-stage high temperature capable of softening said ceramic powders, in said temperature said ceramic powders would sinter and combine with each other so as to combine said insulation layer and said graphite heat conduction layer; wherein said solution is pure water.

17. The manufacturing method of high heat dissipation electric circuit board as claimed in claim 11, wherein said insulation layer is made of ceramic powders, said carrier is vaporized through a first-stage high temperature obtained by a means of high temperature thermal pressing, then said temperature is heated to a second-stage high temperature capable of softening said ceramic powders, in said temperature said ceramic powders would sinter and combine with each other so as to combine said insulation layer and said graphite heat conduction layer.

18. The manufacturing method of high heat dissipation electric circuit board as claimed in claim 11, wherein in the step of installing said graphite heat conduction layer on one side of said insulation layer, for preventing said graphite heat conduction layer from oxidizing under high temperature, inert gas is provided and served as a protection gas during said high temperature processing of said graphite heat conduction layer for avoiding oxidization; wherein said inset gas is nitrogen.

19. The manufacturing method of high heat dissipation electric circuit board as claimed in claim 8, further including a step of forming a plurality of fins on a surface of said graphite heat conduction layer, for increasing the heat dissipation efficiency of said graphite heat conduction layer.

20. The manufacturing method of high heat dissipation electric circuit board as claimed in claim 8, further including a step of installing a metal layer on the surface of graphite heat conduction layer, for preventing said graphite heat conduction layer from powdering.
